(19) United States
(12) Patent Application Publication
(10) Pub. No.: US 2024/0280625 A1
(43) Pub. Date: Aug. 22, 2024

(54) ELECTRICAL EQUIPMENT FAULTS ONLINE DIAGNOSIS AND PREDICTION METHOD

(71) Applicant: SAUDI ARABIAN OIL COMPANY, Dhahran (SA)

(72) Inventor: Abdulaziz Alshalawi, Dammam (SA)

(73) Assignee: SAUDI ARABIAN OIL COMPANY, Dhahran (SA)

(21) Appl. No.: 18/171,220

(22) Filed: Feb. 17, 2023

(51) Int. Cl. G01R 31/12; G06N 3/09

(52) U.S. Cl. CPC G01R 31/1209; G01R 31/1218; G06N 3/09

(57) ABSTRACT

A method for performing preventive examination and maintenance on electrical equipment is disclosed. The method includes training a machine learned model with a database on a server; collecting data for electrical equipment using a plurality of detectors comprising an ultrasound detector, a thermal detector, and a current transformer; analyzing the collected data with the trained machine learned model on the server; outputting results that indicate whether an electrical failure is detected or predicted based on the analysis; and classifying and displaying the results on a device.

### BACKGROUND

An arc flash is a type of electrical explosion or discharge that results from a connection through air to ground or another voltage phase in an electrical system. In arc flash events, large amount of energy is released between two live conductors, causing powerful blast and massive pressure waves. Therefore, preventive examination and maintenance are critical to personal safety and prevent from the hazardous arc flash events. However, as electrical facilities are expending, the burden on maintenance crew to perform the preventive examination and maintenance increase significantly. Thus, a method for performing preventive examination and maintenance on electrical equipment effectively and efficiently is needed.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method that includes training a machine learned model with a database on a server. The method further includes collecting data for electrical equipment using a plurality of detectors including an ultrasound detector, a thermal detector, and a current transformer. The method further includes analyzing the collected data with the trained machine learned model on the server. The method further includes outputting results that indicate whether an electrical failure is detected or predicted based on the analysis. The method further includes classifying and displaying the results on a device.

In general, in one aspect, embodiments relate to a system that includes a plurality of detectors comprising an ultrasound detector, a thermal detector, and a current transformer, the plurality of detectors being configured to obtain data from electrical equipment. The system further includes a server operatively connected to the plurality of detectors that is configured to: analyze the data by applying an machine learned model, and output results that indicate whether an electrical failure is detected or predicted. The system further includes an interface operatively connected to the server and configured to classify and display the results. The machine learned model may be trained with a database on the server.

Other aspects and advantages of the invention will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows a schematic diagram of a neural network in accordance with one or more embodiments.

FIG. 2 shows a schematic diagram of an implementation of a system in accordance with one or more embodiments.

FIG. 3 shows a flowchart in accordance with one or more embodiments.

FIG. 4 shows a flowchart in accordance with one or more embodiments.

FIG. 5 shows a schematic diagram of a computer system in accordance with one or more embodiments.

FIG. 6 shows a schematic diagram of a database in accordance with one or more embodiments.

### DETAILED DESCRIPTION

Specific embodiments of the invention will now be described in detail with reference to the accompanying figures. Like elements in the various figures are denoted by like reference numerals for consistency. Like elements may not be labeled in all figures for the sake of simplicity.

In the following detailed description of embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers does not imply or create a particular ordering of the elements or limit any element to being only a single element unless expressly disclosed, such as by the use of the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a horizontal beam” includes reference to one or more of such beams.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that, one or more of the steps shown in the flowcharts may be omitted, repeated, and/or performed in a different order than the order shown. Accordingly, the scope of the invention should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

In general, embodiments of this disclosure include systems and methods for performing preventive examination and maintenance on electrical equipment effectively and efficiently. In some embodiments, for example, the electrical system components nowadays are increasing drastically with the increase of the new projects and the expansion of existing facilities which increased the burden on maintenance crew to perform the preventive maintenance, inspection and repairs effectively and efficiently. Lack of efficient maintenance of these electrical components results in a decrease in their life expectancy which leads to either major overhaul or complete replacement in addition to operation discrepancies.

One or more embodiments of this disclosure relate to integrating online monitoring with online diagnosis without human intervention, using Artificial Intelligence (AI) and machine learning (ML). One or more embodiments utilize detectors such as ultrasound detectors, instrument current transformers, and thermal cameras, as an input to an Artificial Neural Network (ANN). The one or more embodiments further utilize different classification of outcomes as an output of the ANN to train the machine learned (ML) model in order to identify any equipment issue without the need for equipment shutdown or human intervention. Utilizing the above proposal will save manhours of maintenance crew that can be very expensive and prevent any potential human errors. In addition, one or more embodiments include training a processor to highlight any issue in advance before the issue occurs by identifying the symptoms and expecting the failure.

According to one or more embodiments, the working principle as disclosed herein is based on AI, where multi-input and multi-output data are used to train the specific machine learned model multiple times in order for this ML model to intelligently analyze new inputs and produce an accurate output. The system may include of input detectors, which are ultrasound detector, thermal camera and current transformer. The ultrasound and thermal images are processed through a computer vision algorithm so that useful data can be obtained. Current transformer provides current flow data that can be directly injected in the ML model for training. The detectors may include additional types of sensors. With the multiple input sources, the accuracy level of the present application is improved. Furthermore, the system may utilize a Neural Network (NN) algorithm that is trained with a set of outputs that is assigned with specific input. In other words, the ML model is trained with Supervised Learning.

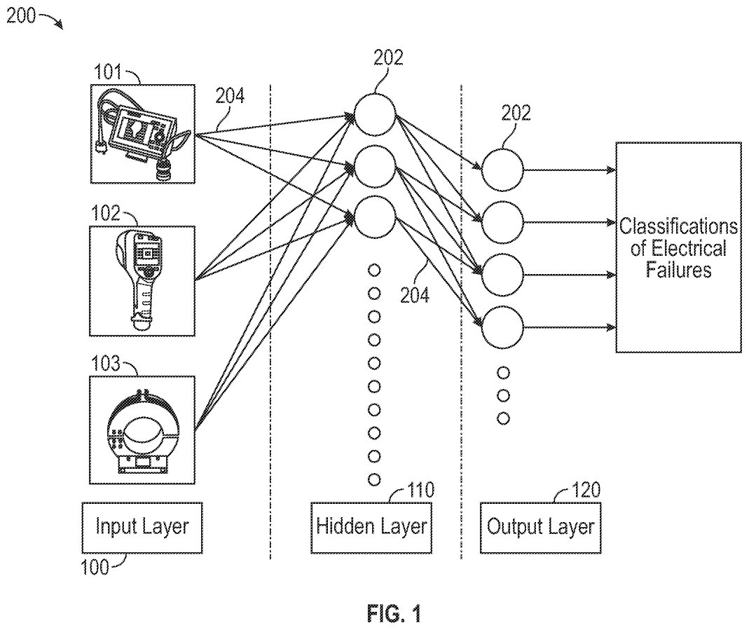

Turning to FIG. 1, FIG. 1 shows a neural network of an electrical fault online diagnosis and prediction system. The neural network 200 includes an input layer 100, a hidden layer 110, and an output layer 120. The system may be used to predict different electrical failures that might cause operation shutdown before these electrical failures happen. With the prediction, the electrical equipment can be rectified immediately or a shutdown may be planned to resolve the issues. This system may be installed in high voltage equipment, fixed type medium voltage equipment, or portable type low voltage equipment.

At a high level, a neural network may be graphically depicted as being composed of nodes 202, where here any circle represents a node, and edges 204, shown here as directed lines. The nodes 202 may be grouped to form layers 100, 110 and 120. FIG. 1 displays three layers of nodes 202 where the nodes 202 are grouped into columns, however, the grouping need not be as shown in FIG. 1. The edges 204 connect the nodes 202. Edges 204 may connect, or not connect, to any node 202 regardless of which layer 100, 110, 120 the nodes 202 are in. That is, the nodes 202 may be sparsely and residually connected. A neural network has at least two layers 100, 110, 120, where the first layer 100 is considered the “input layer” and the last layer 120 is the “output layer”. Any intermediate layer 110 is usually described as a “hidden layer”. A neural network may have zero or more hidden layers 110 and a neural network with at least one hidden layer 110 may be described as a “deep” neural network or as a “deep learning method”. In general, a neural network may have more than one node 202 in the output layer 120. In this case the neural network may be referred to as a “multi-target” or “multi-output” network.

Nodes 202 and edges 204 carry additional associations. Namely, every edge is associated with a numerical value. The edge numerical values, or even the edges 204 themselves, are often referred to as “weights” or “parameters”. While training a neural network, numerical values are assigned to each edge 204. Additionally, every node 202 is associated with a numerical variable and an activation function. Activation functions are not limited to any functional class, but traditionally follow the form

$$A = f ( {\sum }_{i ∈ ( incoming )} [ {( node value )}_{i} {( edge value )}_{i} ] ) , \qquad EQ 1$$

where i is an index that spans the set of “incoming” nodes 202 and edges 204 and f is a user-defined function. Incoming nodes 202 are those that, when viewed as a graph, have directed arrows that point to the node 202 where the numerical value is being computed. Some functions for ƒ may include the linear function ƒ(x)=x, sigmoid function

$$f ( x ) = \frac{1}{1 + {e}^{- x}} ,$$

and rectified linear unit function ƒ(x)=max(0, x), however, many additional functions are commonly employed. Every node 202 in a neural network may have a different associated activation function. Often, as a shorthand, activation functions are described by the function ƒ by which it is composed. That is, an activation function composed of a linear function ƒ may simply be referred to as a linear activation function without undue ambiguity.

When the neural network receives an input, the input is propagated through the network according to the activation functions and incoming node 202 values and edge 204 values to compute a value for each node 202. That is, the numerical value for each node 202 may change for each received input. Occasionally, nodes 202 are assigned fixed numerical values, such as the value of 1, that are not affected by the input or altered according to edge 204 values and activation functions. Fixed nodes 202 are often referred to as “biases” or “bias nodes” (not shown).

Though not shown in FIG. 1, in some implementations, the neural network may contain specialized layers, such as a normalization layer, or additional connection procedures, like concatenation. One skilled in the art will appreciate that these alterations do not exceed the scope of this disclosure.

As noted, the training procedure for the neural network comprises assigning values to the edges 204. To begin training the edges 204 are assigned initial values. These values may be assigned randomly, assigned according to a prescribed distribution, assigned manually, or by some other assignment mechanism. Once edge 204 values have been initialized, the neural network may act as a function, such that it may receive inputs and produce an output. As such, at least one input is propagated through the neural network to produce an output. Training data is provided to the neural network. Generally, training data consists of pairs of inputs and associated targets. The targets represent the “ground truth”, or the otherwise desired output, upon processing the inputs. In the context of the instant disclosure, an input is a seismic dataset and its associated target is a bandwidth extended seismic dataset. During training, the neural network processes at least one input from the training data and produces at least one output. Each neural network output is compared to its associated input data target. The comparison of the neural network output to the target is typically performed by a so-called “loss function”; although other names for this comparison function such as “error function”, “misfit function”, and “cost function” are commonly employed. Many types of loss functions are available, such as the mean-squared-error function, however, the general characteristic of a loss function is that the loss function provides a numerical evaluation of the similarity between the neural network output and the associated target. The loss function may also be constructed to impose additional constraints on the values assumed by the edges 204, for example, by adding a penalty term, which may be physics-based, or a regularization term. Generally, the goal of a training procedure is to alter the edge 204 values to promote similarity between the neural network output and associated target over the training data. Thus, the loss function is used to guide changes made to the edge 204 values, typically through a process called “backpropagation”.

While a full review of the backpropagation process exceeds the scope of this disclosure, a brief summary is provided. Backpropagation consists of computing the gradient of the loss function over the edge 204 values. The gradient indicates the direction of change in the edge 204 values that results in the greatest change to the loss function. Because the gradient is local to the current edge 204 values, the edge 204 values are typically updated by a “step” in the direction indicated by the gradient. The step size is often referred to as the “learning rate” and need not remain fixed during the training process. Additionally, the step size and direction may be informed by previously seen edge 204 values or previously computed gradients. Such methods for determining the step direction are usually referred to as “momentum” based methods.

Once the edge 204 values have been updated, or altered from their initial values, through a backpropagation step, the neural network will likely produce different outputs. Thus, the procedure of propagating at least one input through the neural network, comparing the neural network output with the associated target with a loss function, computing the gradient of the loss function with respect to the edge 204 values, and updating the edge 204 values with a step guided by the gradient, is repeated until a termination criterion is reached. Common termination criteria are: reaching a fixed number of edge 204 updates, otherwise known as an iteration counter; a diminishing learning rate; noting no appreciable change in the loss function between iterations; reaching a specified performance metric as evaluated on the data or a separate hold-out data set. Once the termination criterion is satisfied, and the edge 204 values are no longer intended to be altered, the neural network 200 is said to be “trained.”

Continuing with FIG. 1, the input layer 100 may include input detectors 101-103. The input layer is responsible for receiving the inputs. These inputs can be loaded from an external source such as a web service or a csv file from the database. There must always be one input layer in a neural network. The input layer takes in the inputs, performs the calculations via its neurons and then the output is transmitted onto the subsequent layers. The input detectors 101-103 may include one or more ultrasound detectors 101, one or more thermal detectors 102, and one or more current transformers 103. The detectors may include additional types of sensors without departing from the scope herein. With multiple input sources, the accuracy level of the system may be increased because multiple sources give better confirmation and more data. Further, multiple detectors can detector more electrical issues due to the nature of the detectors.

The input detectors 101-103 are configured to collect data from the equipment through ultrasound detector and thermal images that are processed through computer vision to be useful data in addition the electrical current waveform. Then the input data from the input layer 100 is processed by the hidden layer 110.

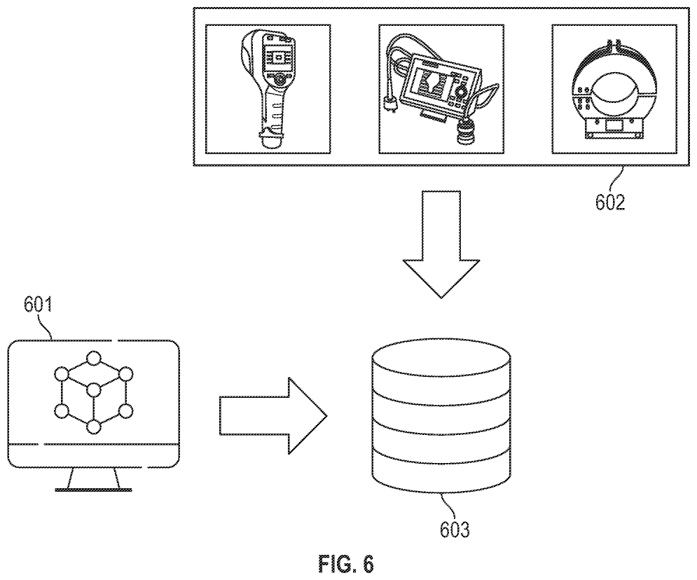

The hidden layer 110 is located between the input and output of the ML model, in which the function applies weights to the inputs and directs them through an activation function as the output. The hidden layer 110 may include one or more intermediate layers and process the data by applying complex non-linear functions. The ML model of the hidden layer 110 is trained with the database 603. For more information regarding the training of the hidden layer, see FIG. 6 below and the accompanying description. After training, the hidden layer may process the detected input of the detectors 101-103 from input layer 100, and output the result to the output layer 120.

The output layer 120 is responsible for producing the result of the detection. The output layer 120 takes in the inputs from the input layer 100, performs the calculations via its neurons through the hidden layer 110 and then the output is computed. The output layer 120 may display the results through an interface, and display the results according to different classifications of the detected electrical failures. Based on the output from the output layer 120, the processor may rectify the electrical equipment accordingly.

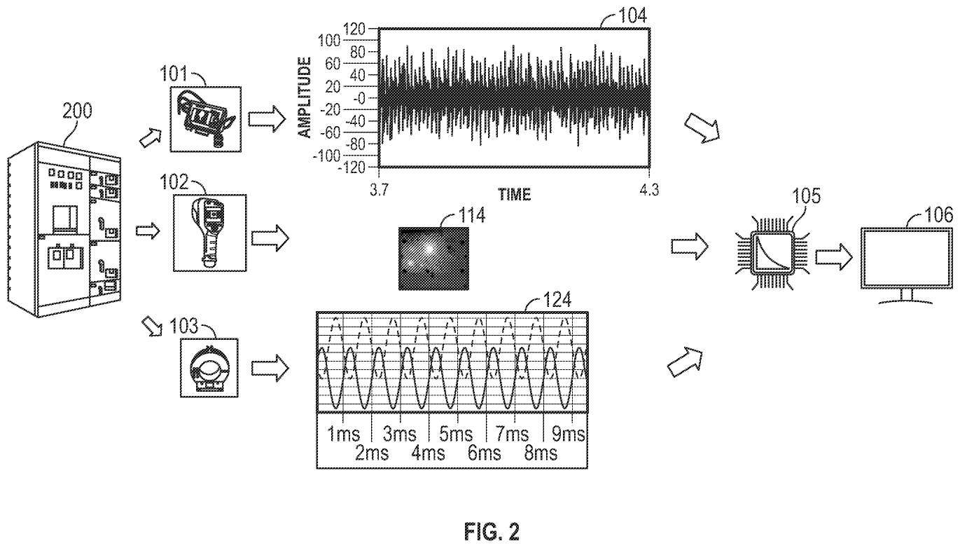

Turning to FIG. 2, FIG. 2 shows an implementation of the electrical fault online diagnosis and prediction system in accordance with one or more embodiments.

As shown in FIG. 2, the detectors 101-103 are used to collect data from the electrical equipment 200. Then, the detected ultrasound data 104, thermal image 114, and current data/waveform 124 are processed by the trained ML model. Based on the analysis, the processor 105 may output the results of the detection and display the results 106. Finally, the system may rectify the electrical equipment based on the results with or without human intervention.

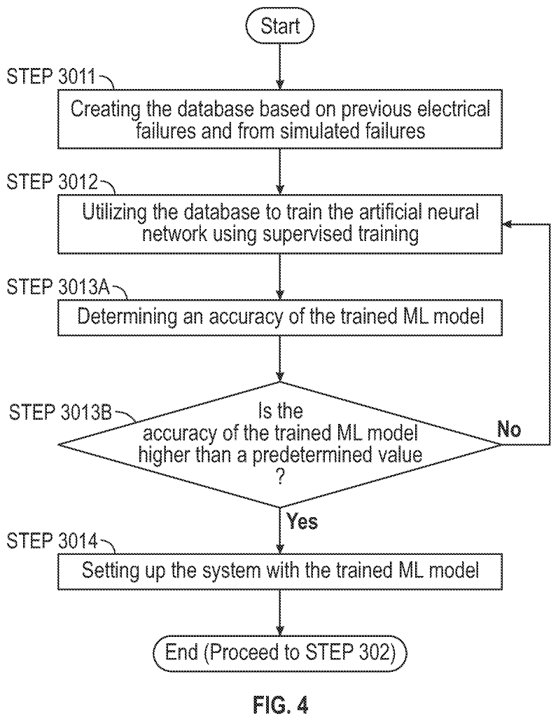

Generally, the ML model may be trained in three phases. Phase 1 includes collecting data stored in the database from previous electrical failures in switchgears, transformers, cables or motors. Failures can be arcing, partial discharge, corona, lose wires or tracking, etc. Failures may also be obtained by simulating the actual failures accurately so they can used to build the database. Phase 2 includes utilizing the database to train the ANN with input and output using supervised machine learning until the ML model achieves a high accuracy in training. Phase 3 includes testing the model by introducing new inputs that were never used in the training to check the accuracy. If the accuracy is high, then the model is considered ready for prediction of other potential failures in electrical equipment. The training phases are described in further detail in FIG. 4.

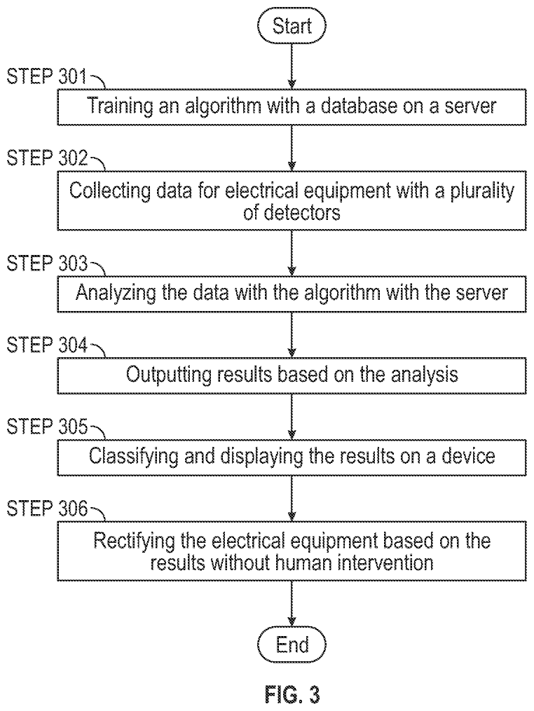

Turning to FIG. 3, FIG. 3 shows a flowchart in accordance with the implementation of FIG. 2. Specifically, the flowchart illustrates the process for applying the system to detect and rectify the electrical faults.

At step 301, the method includes training a ML model with a database 603 on a server. The training process is further clarified in the flowchart of FIG. 4. The database 603 is further explained in FIG. 6.

At step 302, the method includes collecting data for electrical equipment with a plurality of detectors. In the event that the collected raw data (for example, the ultrasound data 104 and thermal image 114 may not be directly applied with the ML model, the collected raw data may be first processed through computer vision algorithm to obtain useful data that could be applied with the ML model. The collected current flow data 124 of current transformer 103 is usually directly applicable to the ML model.

At step 303, the data from above step 302 are analyzed with the ML model with the server. From the analysis, it can be determined if any electrical fault occurs or may occur in the near future.

At step 304, based on the analysis, the method includes outputting the results based on analysis from step 303. The results may indicate whether an electrical failure is detected or predicted.

At step 305, the results may be classified and displayed on a device. For example, the fault “single line-to-ground fault on a transmission line” may be displayed if it is detected that one conductor drops to the ground or comes in contact with the neutral conductor based on the analysis.

At step 306, the method includes rectifying the electrical equipment based on the results. The rectification may be performed with or without human intervention depending on the electrical fault. For example, the system may automatically activate a circuit breaker or relay when abnormal conditions are detected. In such cases, the rectification is performed without human intervention. However, in more complicated scenarios or if severe electrical faults are detected, human intervention may be required.

Turning to FIG. 4, FIG. 4 shows a flowchart for training the ML model.

At step 3011, the method includes creating a database 601 based on previous electrical failures. The database is generated by storing data from previous electrical failures. In one or more embodiments, the database may also be created based on simulated failures. In this case failures on electrical equipment may be simulated using a program and a computing device and the database may store the data associated with the failures. For example, the type of equipment, the type of failure, the threat level of the failure, etc.

At step 3012, the method includes utilizing the database to train the Artificial Neural Network (ANN). The training algorithm may be a machine-learning algorithm that uses supervised training, such as stochastic gradient descent (SGD) or a variant of SGD. For example, the neural network may be a forward model that uses backpropagation and gradients for updating the neural network. Supervised training is characteristic in its use of labeled datasets to train ML models to classify data or predict outcomes accurately. As input data is fed into the model, it adjusts its weights until the model has been fitted appropriately, which occurs as part of a cross validation process.

At step 3013A, the method determines a accuracy of the ML model by introducing new inputs that are never used in the training. At step 3013B, the accuracy of the trained ML model is compared with a predetermined value. If the accuracy is higher than the predetermined value, the model is considered ready to be used for prediction and is set up in step 3014. If the accuracy is lower than the predetermined value, then the model will go back to step 3012 and will be trained again using additional database until the accuracy is higher than the predetermined value.

At step 3014, after the model passed the accuracy determination test, the system may be set up with the model and proceed to step 302 of FIG. 3.

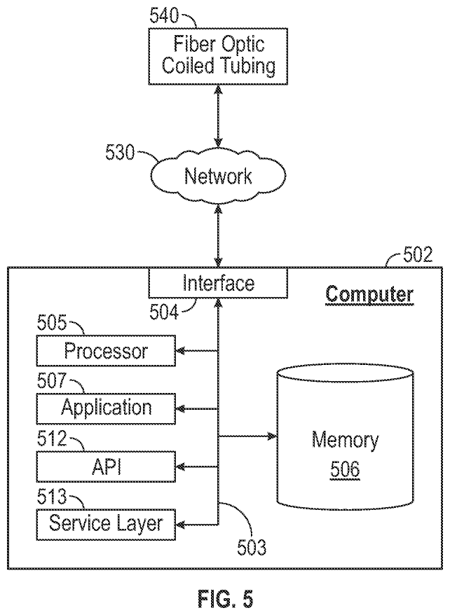

Turning to FIG. 5, embodiments may be implemented on a computer system. FIG. 5 is a block diagram of a computer system 502 used to provide computational functionalities associated with described ML (ML) models, methods, functions, processes, flows, and procedures as described in the instant disclosure, according to an implementation. The illustrated computer 502 is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer 502 may include a computer that includes an input device, such as a keypad, keyboard, touch screen, or other device that can accept user information, and an output device that conveys information associated with the operation of the computer 502, including digital data, visual, or audio information (or a combination of information), or a GUI.

The computer 502 can serve in a role as a client, network component, a server, a database or other persistency, or any other component (or a combination of roles) of a computer system for performing the subject matter described in the instant disclosure. The illustrated computer 502 is communicably coupled with a network 530. In some implementations, one or more components of the computer 502 may be configured to operate within environments, including cloud-computing-based, local, global, or other environment (or a combination of environments).

At a high level, the computer 502 is an electronic computing device operable to receive, transmit, process, store, or manage data and information associated with the described subject matter. According to some implementations, the computer 502 may also include or be communicably coupled with an application server, e-mail server, web server, caching server, streaming data server, business intelligence (BI) server, or other server (or a combination of servers).

The computer 502 can receive requests over network 530 from a client application (for example, executing on another computer 502) and responding to the received requests by processing the said requests in an appropriate software application. In addition, requests may also be sent to the computer 502 from internal users (for example, from a command console or by other appropriate access method), external or third-parties, other automated applications, as well as any other appropriate entities, individuals, systems, or computers.

Each of the components of the computer 502 can communicate using a system bus 503. In some implementations, any or all of the components of the computer 502, both hardware or software (or a combination of hardware and software), may interface with each other or the interface 504 (or a combination of both) over the system bus 503 using an application programming interface (API) 512 or a service layer 513 (or a combination of the API 512 and service layer 513. The API 512 may include specifications for routines, data structures, and object classes. The API 512 may be either computer-language independent or dependent and refer to a complete interface, a single function, or even a set of APIs. The service layer 513 provides software services to the computer 502 or other components (whether or not illustrated) that are communicably coupled to the computer 502. The functionality of the computer 502 may be accessible for all service consumers using this service layer. Software services, such as those provided by the service layer 513, provide reusable, defined business functionalities through a defined interface. For example, the interface may be software written in JAVA, C++, or other suitable language providing data in extensible markup language (XML) format or other suitable format. While illustrated as an integrated component of the computer 502, alternative implementations may illustrate the API 512 or the service layer 513 as stand-alone components in relation to other components of the computer 502 or other components (whether or not illustrated) that are communicably coupled to the computer 502. Moreover, any or all parts of the API 512 or the service layer 513 may be implemented as child or sub-modules of another software module, enterprise application, or hardware module without departing from the scope of this disclosure.

The computer 502 includes an interface 504. Although illustrated as a single interface 504 in FIG. 5, two or more interfaces 504 may be used according to particular needs, desires, or particular implementations of the computer 502. The interface 504 is used by the computer 502 for communicating with other systems in a distributed environment that are connected to the network 530. Generally, the interface 504 includes logic encoded in software or hardware (or a combination of software and hardware) and operable to communicate with the network 530. More specifically, the interface 504 may include software supporting one or more communication protocols associated with communications such that the network 530 or interface's hardware is operable to communicate physical signals within and outside of the illustrated computer 502.

The computer 502 includes at least one computer processor 505. Although illustrated as a single computer processor 505 in FIG. 5, two or more processors may be used according to particular needs, desires, or particular implementations of the computer 502. Generally, the computer processor 505 executes instructions and manipulates data to perform the operations of the computer 502 and any ML models, methods, functions, processes, flows, and procedures as described in the instant disclosure.

The computer 502 also includes a memory 505 that holds data for the computer 502 or other components (or a combination of both) that can be connected to the network 530. For example, memory 505 can be a database storing data consistent with this disclosure. Although illustrated as a single memory 505 in FIG. 5, two or more memories may be used according to particular needs, desires, or particular implementations of the computer 502 and the described functionality. While memory 505 is illustrated as an integral component of the computer 502, in alternative implementations, memory 505 can be external to the computer 502.

The application 507 is an algorithmic software engine providing functionality according to particular needs, desires, or particular implementations of the computer 502, particularly with respect to functionality described in this disclosure. For example, application 507 can serve as one or more components, modules, applications, etc. Further, although illustrated as a single application 507, the application 507 may be implemented as multiple applications 507 on the computer 502. In addition, although illustrated as integral to the computer 502, in alternative implementations, the application 507 can be external to the computer 502.

There may be any number of computers 502 associated with, or external to, a computer system containing computer 502, each computer 502 communicating over network 530. Further, the term “client,” “user,” and other appropriate terminology may be used interchangeably as appropriate without departing from the scope of this disclosure. Moreover, this disclosure contemplates that many users may use one computer 502, or that one user may use multiple computers 502.

In some embodiments, the computer 502 is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Turning to FIG. 6, FIG. 6 shows a database 603. The collected and processed data (i.e., actual failures detected by detectors 602) are stored in the database 603. The database 603 on previous failures with all associated input data is used to train the ML model through supervised training. In one or more embodiments, the ML model may be a neural network.

In one or more embodiments, the database 603 may further include simulated failures 601. For example, when the input database is unavailable or insufficient, the data may be taken from a continuous reading of current systems or may be generated by simulating electrical failure cases many times. The database 603 may be any repository or data structure capable of storing data in any form, such as for example, persistent storage, nonpersistent storage, etc.

Embodiments disclosed herein reduce the need of frequent inspections for electrical equipment by continuously monitoring and predicting failures. There is also a possibility of the system disclosed herein to predict inaccurate numbers due to either insufficient database or inaccurate training algorithm.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method comprising:
training a machine learned model with a database on a server;
collecting data for electrical equipment using a plurality of detectors comprising an ultrasound detector, a thermal detector, and a current transformer;
analyzing the collected data with the trained machine learned model on the server;
outputting results that indicate whether an electrical failure is detected or predicted based on the analysis; and
classifying and displaying the results on a device.

2. The method of claim 1, wherein the training further comprises:
creating the database based on previous electrical failures and simulated electrical failures;
utilizing the database to train the machine learned model using supervised machine learning;
determining an accuracy of the machine learned model by testing the machine learned model;
wherein when the accuracy of the machine learned model is lower than a predetermined value, training the machine learned model using additional database until the accuracy is higher than or equal to the predetermined value;
wherein when the accuracy of the machine learned model is higher than or equal to a predetermined value, setting up the machine learned model for analyzing the data.

3. The method of claim 1, further comprising rectifying the electrical equipment based on the results without human intervention.

4. The method of claim 1, wherein the ultrasound detector detects ultrasounds and process the detected ultrasounds through a computer vision machine learned model.

5. The method of claim 1, wherein the thermal detector generates thermal images and process the generated thermal images through a computer vision machine learned mode.

6. The method of claim 1, wherein the current transformer generates current flow data that are directly input into the machine learned model.

7. The method of claim 2, wherein the simulated electrical failures are simulated and recorded continuously until sufficient data are acquired.

8. The method of claim 2, wherein the supervised training trains the machine learned model using outputs that are assigned with specific inputs of the database.

9. The method of claim 2, wherein the accuracy is determined by testing the machine learned model with new inputs that are not used in the database for training the machine learned model.

10. The method of claim 1, wherein the machine learned model is a neural network.

11. The method of claim 1, wherein the electrical equipment comprises switchgears, transformers, cables or motors.

12. The method of claim 1, wherein the electrical failure is one of arcing, partial discharge, corona, loose wires or tracking issue.

13. A system comprising:
a plurality of detectors comprising an ultrasound detector, a thermal detector, and a current transformer, the plurality of detectors being configured to obtain data from electrical equipment;
a server operatively connected to the plurality of detectors that is configured to:
analyze the data by applying an machine learned model, and output results that indicate whether an electrical failure is detected or predicted; and
an interface operatively connected to the server and configured to classify and display the results,
wherein the machine learned model is trained with a database on the server.

14. The system of claim 13, wherein the machine learned model is trained by:
creating the database based on previous electrical failures and simulated electrical failures;
utilizing the database to train the machine learned model using supervised training;
determining an accuracy of the machine learned model by testing the machine learned model;
wherein when the accuracy of the machine learned model is lower than a predetermined value, training the machine learned model using additional database until the accuracy is higher than or equal to the predetermined value;
wherein when the accuracy of the machine learned model is higher than or equal to a predetermined value, setting up the machine learned model for analyzing the data.

15. The system of claim 14, wherein the accuracy is determined by testing the machine learned model with new inputs that were not used in the database for training the machine learned model.
